(19) United States
(12) Patent Application Publication
(10) Pub. No.: US 2026/0292979 A1
(43) Pub. Date: Sep. 24, 2026

(54) HIGHER CURRENT SURFACE MOUNT PADS AND CIRCUIT ASSEMBLY

(71) Applicant: Infineon Technologies Austria AG, Villach (AT)

(72) Inventors: EungSan CHO, Torrance, CA (US); Sutej Reddy CHALLA, Smithtown, NY (US); Toni SALMINEN, München (DE)

(21) Appl. No.: 19/088,049

(22) Filed: Mar. 24, 2025

(51) Int. Cl. H05K 1/11; H05K 1/14; H05K 1/18; H05K 3/10

(52) U.S. Cl. CPC H05K 1/111; H05K 1/144; H05K 1/181; H05K 3/108; H05K 2201/0191; H05K 2201/041; H05K 2201/094

(57) ABSTRACT

A circuit assembly includes a first circuit substrate and at least at first surface mount pad. The first surface mount pad may be disposed on a first surface of the first circuit substrate, where the first surface mount pad includes a base surface mount pad and a supplemental conductive element fabricated on the base surface mount pad such that the base surface mount pad is disposed between the first circuit substrate and the supplemental conductive element such as fabricated from metal. The first circuit substrate may further include a second surface mount pad. The height of the first surface mount pad may be greater than the height of the second surface mount pad. The high-profile height of the first surface mount pad supports a higher current throughput than the low-profile height second surface mount pad.

### BACKGROUND

Conventional circuits typically include one or more surface mount pads. The surface mount pads provide connectivity between circuit components and traces in or on a corresponding circuit board.

More specifically, a so-called surface mount pad may be a reserved area on a surface of a printed circuit board, where a surface mount component is soldered directly onto the surface of the printed circuit board via the surface mount pad. The implementation of surface mount technology enables a higher density of connecting respective circuit components to the circuit board than through-hole mounting techniques, resulting in a smaller overall circuit assembly.

Thus, a conventional surface mount pad is generally a flat surface area on a circuit board, where the surface mount pad is fabricated from metal such as copper or other suitable metal. During fabrication of a respective circuit assembly, a fabrication tool applies solder paste on the surface mount pad and/or a respective pin of a surface mount component. The fabrication tool contacts the respective pin of the surface mount component to the surface mount pad, where the solder paste resides between surface mount pad and the respective pin. The fabrication tool then applies sufficient heat to temporarily melt the solder paste. After cooling, the remaining homogeneous mass of solder between the respective pin and the surface mount pad of the circuit board ensures that the surface mount component is securely affixed to the circuit substrate. The remaining mass of solder also provides electrical connectivity between the surface mount pad and the pin of the surface mount component.

### BRIEF DESCRIPTION

This disclosure includes the observation that conventional surface pads disposed on a conventional circuit board do not support conveyance of sufficiently high current between a circuit and a corresponding circuit component.

Examples herein provide novel and improved connectivity between surface mount components and a respective circuit.

More specifically, as discussed herein, a fabricator entity fabricates a circuit assembly to include a first circuit substrate (such as any circuit component, circuit assembly, circuit, circuit board, etc.) and one or more surface mount pads such as including at least at a first surface mount pad. The first surface mount pad of the first circuit substrate may be disposed on a first surface of the first circuit substrate. The first surface mount pad may be fabricated from a homogeneous mass of electrically conductive material. In such an instance, the homogeneous mass of electrically conductive material represents the first surface mount pad disposed on the first surface of the first circuit substrate. Alternatively, the first surface mount pad may be fabricated to include a base surface mount pad and a supplemental conductive element fabricated on the base surface mount pad. In this latter instance, the base surface mount pad is disposed between the first circuit substrate and the supplemental conductive element such as fabricated from metal.

Note further that the first circuit substrate may further include a second surface mount pad disposed on the first surface of the first circuit substrate, where the first surface mount pad can be configured to include supplemental conductive material applied to the base surface mount pad to increase its height. The height of the first surface mount pad (such as combination of base surface mount pad and the supplemental conductive element or material) may be greater than the height of the second surface mount pad. In such an instance, the first circuit substrate may include multiple surface mount pads, where the first surface mount pad may be fabricated to be greater in height than the second surface mount pad.

Accordingly, an apparatus as discussed herein may include a first circuit substrate; a first surface mount pad; and a second surface mount pad. The first surface mount pad may be disposed on a first surface of the first circuit substrate, where the first surface mount pad is fabricated in accordance with a first height with respect to the first surface; the second surface mount pad may be disposed on the first surface of the first circuit substrate, where the second surface mount pad is fabricated in accordance with a second height with respect to the first surface, the first height may be greater than the second height.

Fabrication and implementation of the first surface pad (higher height profile surface pad of heterogeneous or homogeneous material with respect to the second surface mount pad) supports a higher current flow capability than a current flow capability supported by the second surface pad (such as a lower height profile surface pad).

It is further noted that each of the surface mount pads (such as including the first surface mount pad) disposed on the first circuit substrate can be configured to include at least one void, where the at least one void can be configured to include a first void disposed in a middle of the first surface mount pad.

Still further, the first surface mount pad can be configured to include a first void extending between a first side of the first surface mount pad and a second side of the first surface mount pad. The first void can be configured to provide separation between a first portion of the first surface mount pad and a second portion of the first surface mount pad.

In yet another example, the assembly as discussed herein can be configured to include a layer of insulative material (insulation material) disposed on the first surface of the first circuit substrate, where the layer of material at least partially covers a first portion of a top surface of the second surface mount pad. The layer of insulative material can be configured to include a first opening. The first surface mount pad can be configured to extend through the first opening of the insulative material. The layer of insulative material can be configured to include a second opening, where the second opening exposes a second portion of a top surface of the second surface mount pad.

In still further examples, the apparatus such as assembly or other suitable entity as discussed herein can be configured to include a first mass of solder material in contact with the first surface mount pad and a second mass of solder material in contact the second surface mount pad. At least a portion of the first mass of solder material contacts a top surface of the first surface mount pad and a side surface of the first surface mount pad. The second mass of solder contacts a top surface of the second surface mount pad.

Further examples of the apparatus as discussed herein include a second circuit substrate, where the second circuit substrate can be configured to include a third surface mount pad and a fourth surface mount pad. The third surface mount pad and the fourth surface mount pad may be disposed on a first surface of the second circuit substrate. The apparatus may further include a first solder joint extending between the first surface mount pad and the third surface mount pad. The apparatus may further include a second solder joint extending between the second surface mount pad and the fourth surface mount pad.

In one example, the third surface mount pad is fabricated in accordance with a third height with respect to the first surface of the second circuit substrate; the fourth surface mount pad is fabricated in accordance with a fourth height with respect the first surface of the second board substrate. In one example, the third height is substantially equal to the fourth height. Alternatively, the third height may be greater than the fourth height.

The apparatus may further include a first gap that is filled with a first mass of solder between the first surface mount pad and the third surface mount pad. The apparatus may further include a second gap that is filled with a second mass of solder between the second surface mount pad and the fourth surface mount pad. The first gap may be smaller than the second gap for a number of reasons. For example, recall that the first surface mount pad may be taller than the second surface mount pad. Additionally, the third surface mount pad may be taller than the fourth surface mount pad.

In another example, the apparatus further includes a second circuit substrate, a first solder joint, and a second solder joint. The second circuit substrate can be configured to include a third surface mount pad and a fourth surface mount pad, where the third surface mount pad and the fourth surface mount pad are disposed on a first surface of the second circuit substrate. The first solder joint can be configured to extend between the first surface mount pad and the third surface mount pad. The second solder joint can be configured to extend between the second surface mount pad and the fourth surface mount pad. The first circuit substrate and corresponding first surface may be spaced apart from the second circuit substrate and corresponding first surface by a distance X. A magnitude of the first height of the first surface mount pad may be between 50 percent and 90 percent of the distance X. The increased height of the first surface mount pad displaces what would otherwise be part of the first solder joint.

In a further example implementation, the first circuit substrate can be configured to include any suitable circuitry. In one example, the first circuit substrate includes an embedded voltage regulator circuit (such as a power converter circuit or other suitable entity) operative to: i) receive an input voltage from the first surface mount pad, ii) convert the input voltage into an output voltage, and iii) output the output voltage from a second surface of the first circuit substrate to a load, where the second surface of the first circuit substrate faces an opposite direction than the second surface of the first circuit substrate.

Further examples as discussed herein include methods of fabricating one or more surface mount pads and corresponding circuit assemblies. In one example, as further discussed herein, a method of fabricating a circuit assembly includes: receiving a first circuit substrate; fabricating a first surface mount pad on a first surface of the first circuit substrate, the first surface mount pad fabricated in accordance with a first height with respect to the first surface of the first circuit substrate; and fabricating a second surface mount pad on the first surface of the first circuit substrate, the second surface mount pad fabricated in accordance with a second height with respect to the first surface of the first circuit substrate. The second height may be greater than the first height.

As previously discussed, an initial height of the second surface mount pad (or base portion of the second surface mount pad) with respect to the first surface is substantially equal to the first height of the first surface mount pad. Fabrication of the second surface mount pad may further include, via a fabrication system: applying a mask layer to the first surface of the first circuit, where the mask layer may cover the first surface mount pad, the mask layer may include an opening exposing the second surface mount pad; and applying electrically conductive material in the opening to increase a height of the second surface mount pad with respect to the first surface, where the mask layer prevents application of the electrically conductive material to the first surface mount pad. Additionally, the fabricator removes the mask layer from the first surface to expose the first surface mount pad and the second surface mount pad.

Yet further, if desired, the fabricator fabricates the second surface mount pad to include at least one void to increase an exposed surface area of the second surface mount pad.

These and other more specific examples are disclosed in more detail below.

Note further that although examples as discussed herein are applicable to fabrication of circuit assemblies such as power converter assemblies, the concepts disclosed herein may be advantageously applied to any other suitable topologies.

Additionally, note that although each of the different features, techniques, configurations, etc., herein may be discussed in different places of this disclosure, it is intended, where suitable, that each of the concepts can optionally be executed independently of each other or in combination with each other. Accordingly, the one or more present inventions as described herein can be embodied and viewed in many different ways.

Also, note that this preliminary discussion of examples herein (BRIEF DESCRIPTION OF EXAMPLES) purposefully does not specify every example and/or incrementally novel aspect of the present disclosure or claimed invention(s). Instead, this brief description only presents general examples and corresponding points of novelty over conventional techniques. For additional details and/or possible perspectives (permutations) of the invention(s), the reader is directed to the Detailed Description section (which is a summary of examples) and corresponding figures of the present disclosure as further discussed below.

### BRIEF DESCRIPTION OF THE DRAWINGS

FIG. 1 is an example diagram illustrating a side view of a circuit assembly including implementation of multiple heightened surface mount pad and multiple different types of surface mount pads as discussed herein.

FIG. 2 is an example side view diagram illustrating implementation of different types of surface mount pads and corresponding solder joints providing low impedance connectivity between a first circuit and a second circuit as discussed herein.

FIG. 3 is an example side view diagram illustrating implementation of different types of surface mount pads and solder joints providing connectivity between a host circuit substrate and multiple pins of a power converter circuit assembly as discussed herein.

FIG. 4 is an example side view diagram illustrating fabrication of multiple high current surface pads on a circuit substrate as discussed herein.

FIG. 5 is an example side view diagram illustrating implementation of multiple high current surface pads on a substrate as discussed herein.

FIG. 6 is an example side view diagram illustrating different shapes of multiple high current surface pads and multiple low current surface pads disposed on a respective circuit substrate as discussed herein.

FIG. 7A is an example side view diagram illustrating implementation of a circuit path between a first standard surface pad and a second standard surface pad as discussed herein.

FIG. 7B is an example side view diagram illustrating implementation of a circuit path between a standard surface pad and a high-current surface pad as discussed herein.

FIG. 7C is an example side view diagram illustrating implementation of a circuit path between a first high-current surface pad disposed on a first circuit substrate and a second high-current surface pad disposed on a second circuit substrate as discussed herein.

FIG. 8 is an example top view diagram illustrating different configurations of surface mount pads as discussed herein.

FIG. 9 and FIG. 10 are example side view diagrams illustrating a process of providing circuit path connectivity between multiple circuit assemblies as discussed herein.

FIG. 11 is an example side view diagram illustrating different implementations of surface pads and corresponding solder joints on multiple circuit substrates to provide connectivity as discussed herein.

FIG. 12 is an example diagram illustrating a method of implementing one or more surface mount pads as discussed herein.

The foregoing and other objects, features, and advantages of examples herein will be apparent from the following more particular description herein, as illustrated in the accompanying drawings in which like reference characters refer to the same parts throughout the different views. The drawings are not necessarily to scale, with emphasis instead being placed upon illustrating the examples, principles, concepts, etc.

### DETAILED DESCRIPTION

A circuit assembly includes a first circuit substrate and at least at first surface mount pad. The first surface mount pad may be disposed on a first surface of the first circuit substrate or other relation with respect to the first circuit substrate, where the first surface mount pad (such as a high profile surface mount pad) can be configured to include a base surface mount pad and a supplemental conductive element fabricated on the base surface mount pad such that the base surface mount pad is disposed between the first circuit substrate and the supplemental conductive element such as fabricated from metal. If desired, alternatively, the first surface mount pad of increased height with respect to a standard surface mount pad is fabricated as a homogeneous element instead of being fabricated from a combination of a base surface mount pad and supplemental conductive element. It is further noted that the first circuit substrate may further include a second surface mount pad. The height of the first surface mount pad may be greater than the height of the second surface mount pad. Accordingly, in certain instances, a circuit board substrate can be configured to include surface mount pads of different heights.

As further discussed herein, implementation of one or more high-profile surface mount pads are useful in applications requiring high current conveyance with lower power losses resulting in dissipation of less unwanted heat. Accordingly, the implementation of novel surface mount pads as discussed herein results in greater power conversion efficiency because there are less losses associated with conveyance of the power through the high-profile surface mount pads.

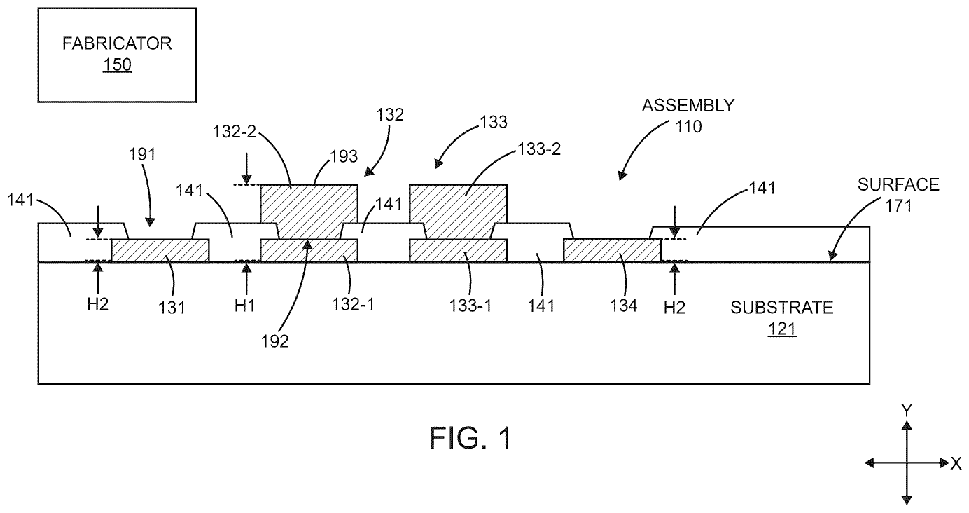

Now, more specifically, with reference to the drawings, FIG. 1 is an example diagram illustrating a side view of a circuit assembly including implementation of multiple different types of surface mount pads as discussed herein.

As shown in FIG. 1, the fabricator 150 produces the assembly 110. The assembly 110 includes substrate 121 and multiple surface mount pads 131, 132, 133, 134, etc., disposed on a surface 171 of the substrate 121.

Note that the substrate 121 can be any suitable entity such as a circuit board assembly, semiconductor chip, circuit component, electronic part, circuit device, etc.

Further in this example, the multiple surface mount pads include surface mount pad 131 (a.k.a., electrically conductive element), surface mount pad 132 (a.k.a., electrically conductive element), surface mount pad 133 (a.k.a., electrically conductive element), and surface mount pad 134 (a.k.a., electrically conductive element).

The assembly 110 may include any number of surface mount pads. The assembly 110 further includes insulative material 141 disposed on the surface 171 of the substrate 121. As its name suggests, the influence of material 141 provides electrical isolation between the surface pads.

Note again that the circuit substrate 121 may be any suitable entity such as a circuit, assembly, circuit component, etc., on which surface mount pads are fabricated. As their names suggest, the surface mount pads of the assembly 110 corresponding substrate 121 provide a way to connect the substrate 121 and corresponding traces in the substrate 121 to another circuit (hardware, device, component, circuit board, etc.) coupled to the surface 171 of the substrate 121.

In yet a further example, it is noted that the surface mount pad 132 may be a two-part (or any number of layers or parts) component including a combination of base surface mount pad 132-1 and supplemental conductive element 132-2 (such as fabricated from copper or other suitable metal or metal alloy). For example, the fabricator 150 can be configured to fabricate the base surface mount pad 132-1 on a surface 171 of the substrate 121.

Each of the base surface mount pad 132-1 and the base surface mount pad 133-1 may be of height H2 similar to heights of the surface mount pad 131 and the surface mount pad 134. In other words, the fabricator 150 can be configured to first fabricate the multiple surface mount pads including surface mount pad 131, surface mount pad 132-1, surface mount pad 133-1, and surface mount pad 134 onto the substrate 121.

Subsequent to fabrication of the base surface mount pads 131, 132-1, 133-1, 134, etc., the fabricator 150 applies or affixes the supplemental conductive element 132-2 to a top surface 192 of the surface mount pad 132-1 (such as fabricated from one or more layers of applied copper or other suitable metal or metal alloy to the top surface 192). The exposed top surface 193 and one or more side surfaces of the supplemental conductive element 132-2 (a.k.a., surface mount pad) supports connectivity to any suitable entity such as via soldering or other technique.

The supplemental conductive element 132-2 can be fabricated based on any suitable shape or size. The surface mount pad 132 also may be fabricated as a homogeneous element of metal or metal alloy.

The surface mount pad 133 may be a two-part component (multi-part component of any number of layers to extend the respective height) including base surface mount pad 133-1 and supplemental conductive element 133-2 (such as fabricated from copper or other suitable metal or metal alloy). For example, the fabricator 150 can be configured to fabricate the base surface mount pad 133-1 on the substrate 121. The fabricator 150 applies or affixes the supplemental conductive element 133-2 to a top surface of the surface mount pad 133-1. The exposed top surface of the supplemental conductive element 133-2 is an extension surface pad supporting connectivity to any suitable entity.

The supplemental conductive element 133-2 can be fabricated based on any suitable shape or size. The surface mount pad 133 also may be fabricated as a homogeneous element of metal or metal alloy.

Thus, it is noted that the taller surface mount pads disposed on the substrate 121 such as surface mount pad 132, surface mount pad 133, etc., may be fabricated as a homogeneous electrically conductive element (such as via a first metal or metal alloy). This means that the surface mount pad 132 may be fabricated as a single homogeneous component or multiple components.

The taller surface mount pads (higher profile surface mount pad) such as surface mount pad 132, surface mount pad 133, etc., may be fabricated as a heterogeneous electrically conductive element (such as via a multiple metals or multiple metal alloys). Accordingly, the fabricator 150 can be configured to fabricate the surface mount pad 132 via first fabricating the surface mount pad 132-1 and then applying the supplemental conductive element 132-2 to produce the surface mount pad 132.

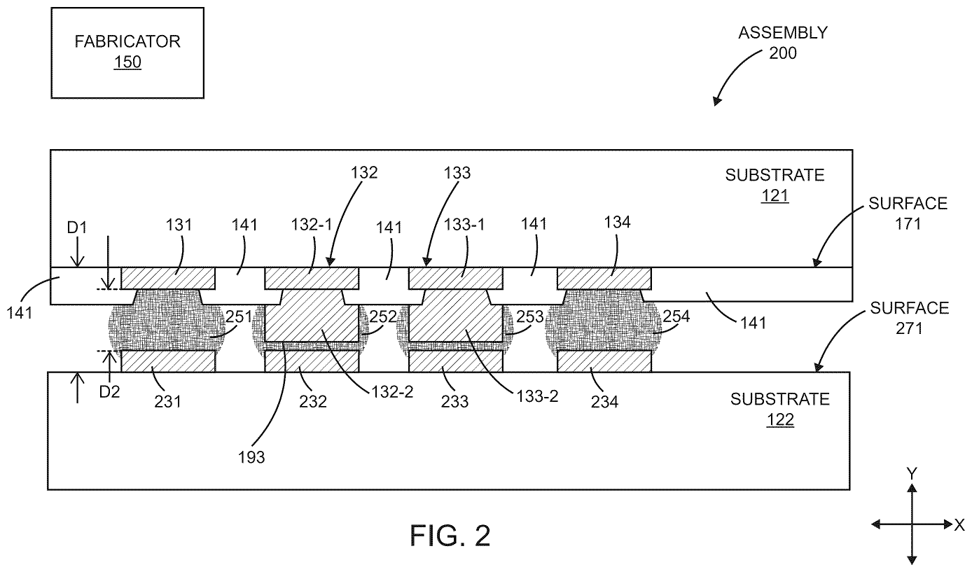

Note that the surface 171 and the substrate 121 can be configured to include any number of surface mount pads (such as of the first surface mount pad type as indicated by surface mount pad 131, 134, etc.) or surface mount pads (such as of a second surface mount pad type as illustrated by surface mount pad 132, 133, etc.) for connecting respective traces on the substrate 121 to pins or traces of other circuit hardware. FIG. 2 illustrates an example of providing connectivity of the substrate 121 to another substrate.

Referring again to FIG. 1, it is noted that the fabricator 150 can be configured to fabricate each of the surface mount pads to be a certain desirable height such as with respect to the base surface mount pad or with respect to the surface 171 of the substrate 121.

For example, as shown in FIG. 1, and as previously discussed, the fabricator 150 can be configured to initially fabricate the surface mount pads 131, 132-1, 133-1, 134, etc., to be of a height H2 (low height) with respect to the surface 171.

Additionally, the fabricator 150 chooses one or more of the surface mount pads in which to increase a height with respect to a height H2 of the base surface mount pad (surface mount pads 131, 132-1, 133-1, 134, etc. ,).

For example, the fabricator 150 can be configured to choose surface pad 132-1 and surface pad 133-1 to produce higher profile surface pads of height H2. In other words, in this example, the fabricator 150 chooses to produce the surface mount pad 132-1 and the surface mount pad 133-1 to support a higher flow of current than the surface mount pads 131 and 134. In such an instance, the fabricator 150 fabricates the surface mount pad 132 to include the supplemental conductive element 132-2 directly coupled to the top surface 192 or potentially side surfaces of the surface mount pad 132-1. The exposed surface associated with the surface mount pad 132 such as on a top side 193 of the supplemental conductive element 132-2 stands at a height of H1 with respect to the surface 171 of the circuit substrate 121. Thus, the one or more layers of metal or other suitable material applied by the fabricator 150 to the top surface 192 to fabricate the surface mount pad 132-2 increases the overall height of the surface mount pad 132 to be height H1.

Additionally, via one or more applied layers of metal or other suitable material, the fabricator 150 further fabricates the surface mount pad 133 to include the supplemental conductive element 133-2 directly coupled to a top surface of the surface mount pad 133-1. The exposed surface on a top side of the supplemental conductive element 133-2 stands at a height of H1 with respect to the surface 171 of the circuit substrate 121.

In such an instance, both the surface mount pad 132 and the surface mount pad 133 have a higher height profile than the surface mount pad 131 and surface mount pad 134.

As further discussed herein, the modified (higher profile or taller) surface mount pads such as surface mount pad 132, surface mount pad 133, etc., provide higher current flow capability than the standard surface mount pads 131, 134, etc. This is because the supplemental conductive element 132-2 and the supplemental conductive element 133-2 are fabricated from metal and displace what would otherwise be solder providing a connection between the substrate 121 and another circuit component circuit assembly.

In other words, the metal or metal alloy use to fabricate the supplemental conductive element 132-2 and the supplemental conductive element 133-2 can be configured to have a lower resistivity than a resistivity of solder. Stated differently, and as further shown herein, the metal or metal alloy used to fabricate the supplemental conductive element 132-2 and the supplemental conductive element 133-2 provide a higher magnitude of electrical conductivity than an electrical conductivity of solder.

In summary, examples herein include an assembly 110 including a first circuit substrate 121 and surface mount pad 132, where the assembly 110 may further include a surface mount pad 131, where the surface mount pad 131 is substantially similar to the base surface mount pad 132-1. The height H1 of the surface mount pad 132 (such as combination of base surface mount pad 132-1 and the supplemental conductive element 132-2) may be greater than the height H2 of the surface mount pad 131.

Additionally, an apparatus as discussed herein may include a first circuit substrate 121; a first surface mount pad 132; and a second surface mount pad 131. The first surface mount pad 132 may be disposed on a first surface 171 of the first circuit substrate 121, where the first surface mount pad 132 is fabricated in accordance with a first height H1 with respect to the first surface 171; the second surface mount pad 131 may be disposed on the first surface 171 of the first circuit substrate 121, where the second surface mount pad 131 is fabricated in accordance with a second height H2 with respect to the first surface 171. The height H2 of the surface mount pad 131 is less than the height H1 of the surface mount pad 132.

As previously discussed, fabrication and implementation of the surface pad 132 (higher height profile H1 surface pad of heterogeneous or homogeneous material) supports a higher current flow capability than a current flow capability supported by the second surface pad (such as a lower height H2 profile surface pad).

In yet another example, the assembly 110 as discussed herein can be configured to include a layer of insulative material 141 disposed on the first surface 171 of the first circuit substrate 121, where the layer of insulative material 141 at least partially covers a first portion of a top surface of the surface mount pad 131, surface mount pad 134, etc. The layer of insulative material 141 can be configured to include opening 191 and opening 192 in any number of openings. The surface mount pad 132 can be configured to extend from the surface 171 and through the opening 192 of the insulative material 141. As previously discussed, the insulative material 141 (a.k.a., insulator material such as non-electrically conductive material) may partially cover a first portion of a top surface of the surface mount pad 131 as shown in FIG. 1. The opening 191 in the layer of insulative material 141 can be configured to expose a second portion of the top surface of the second surface mount pad 131.

FIG. 2 is an example side cross-section cutaway view diagram illustrating implementation of different types of surface mount pads and solder joints providing connectivity between a first circuit and a second circuit as discussed herein.

In this example, the fabricator 150 provides solder connectivity between the substrate 121 and the substrate 122 to produce the assembly 200. The substrate 122 may be any suitable entity such as a circuit board, circuit component, device, etc.

For example, as shown in FIG. 2, the fabricator 150 receives substrate 121 (as previously discussed in FIG. 1) as well as receives substrate 122. Substrate 122 includes multiple surface mount pads 231, 232, 233, and 234 disposed on the surface 271 of the substrate 122. The substrate 122 can be configured to include any number of surface mount pads. Each of the surface mount pads on the substrate 122 may be of the same or different height with respect to the surface 271.

The fabricator 150 produces the assembly 200 to include substrate 121 coupled to substrate 122 via solder connections between the surface mount pads. For example, the fabricator 150 supplies a mass of solder 251 and then heats the mass of solder 251 (above its respective melting point) between the surface mount pad 131 and the surface mount pad 231; the subsequent cooled mass of solder 251 (now homogeneous solid) provides an electrically conductive path between the surface mount pad 131 of the substrate 121 and the surface mount pad 131 of the substrate 122.

Additionally, the fabricator 150 supplies a mass of solder 252 and then heats the mass of solder 252 (above its respective melting point) between the surface mount pad 132 and the surface mount pad 232; the subsequent cooled mass of solder 252 provides an electrically conductive path between the surface mount pad 132 of the substrate 121 and the surface mount pad 232 of the substrate 122.

Additionally, the fabricator 150 supplies and then heats a mass of solder 253 between the surface mount pad 133 and the surface mount pad 233; the cooled mass of solder 253 provides an electrically conductive path between the surface mount pad 133 of the substrate 121 and the surface mount pad 233 of the substrate 122.

Additionally, the fabricator 150 supplies and then heats a mass of solder 254 between the surface mount pad 134 and the surface mount pad 234; the mass of solder 254 provides an electrically conductive path between the surface mount pad 134 of the substrate 121 and the surface mount pad 234 of the substrate 122.

Thus, in this example, the apparatus such as the assembly 200 further includes substrate 121, substrate 122, a first solder joint (251), and a second solder joint (252). The substrate 121 includes surface pad 131 (height H2) and surface pad 132 (height H1), each of different heights. The substrate 122 can be configured to include surface pad 231 and surface pad 232 disposed on a surface 271 of the substrate 122. The surface pad 231 and the surface pad 232 may be of the same height or, as discussed later in the specification, different heights.

The first solder joint (251) can be configured to extend between the surface mount pad (131) and the surface mount pad (231). The second solder joint (252) can be configured to extend between the surface mount pad (132) and the surface mount pad (232).

The surface 171 of the first circuit substrate 121 or respective surface pad 131 may be spaced apart from the first surface 271 of the second circuit substrate 122 or respective surface pad 231 by a distance D1 or D2 (X). A magnitude of the first height H1 of the surface mount pad 131 may be between 50 percent and 90 percent of the distance X (D1 and D2). In such an instance, presence of the surface pad 132 having a height of H1 substantially reduces a corresponding remaining gap between the bottom surface of the surface pad 132 (surface 193) and the top surface of the surface pad 232. Accordingly, overall, the heightened surface pad 132 provides a lower resistive path between the surface pad 132 and the surface pad 232 because the supplemental conductive material used to fabricate the surface pad 132-2 has a lower resistivity than the mass of solder 252.

The heightened profile of the surface mount pad 132 such as surface mount pad 132-2 also includes exposed side surfaces to which respective portions of the solder 252 adhere. In other words, the heightened profile of the surface mount pad 132 provides extra exposed surface areas of respective metal associated with the surface mount pad 132-2 to provide connectivity.

Accordingly, in one example, at least a portion of the first mass of solder material (252) contacts a top surface of the surface pad 232 as well as bottom surface (193) and side surfaces of the surface pad 132-2.

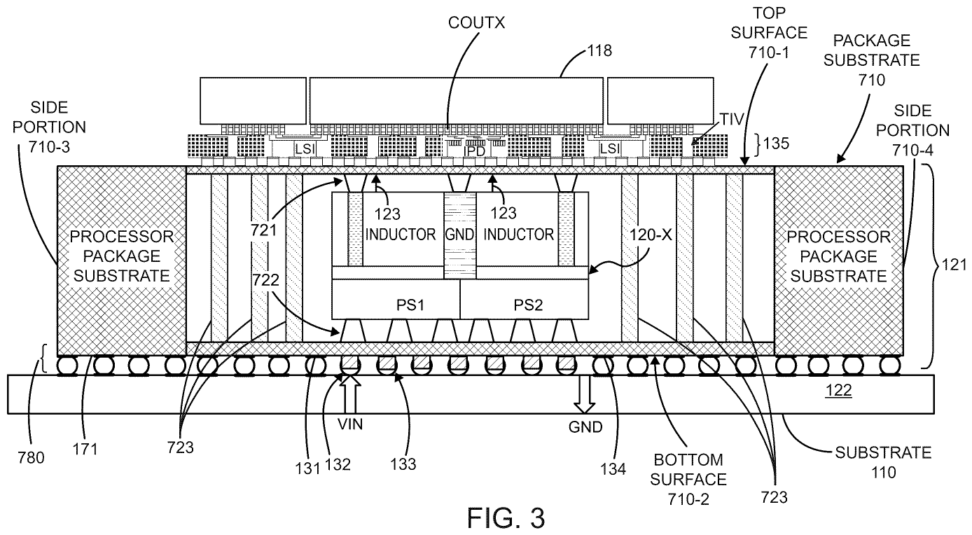

FIG. 3 is an example side view diagram illustrating implementation of different types of surface mount pads and solder joints providing connectivity between a host circuit substrate and multiple pins of a power converter circuit assembly as discussed herein.

In a further example implementation, the first circuit substrate 121 can be configured to include an embedded voltage regulator circuit 120-X operative to: i) receive an input voltage Vin from the first surface mount pad 132, ii) convert the input voltage Vin into an output voltage 123, and iii) output the output voltage 123 from a second surface 710-1 of the first circuit substrate 121 to a load 118, the second surface 710-1 of the first circuit substrate 121 facing an opposite direction than the first surface 171 of the first circuit substrate 121.

In this example, one or more instances of the power converter assembly 120-X is disposed in a respective packet substrate 710. The package substrate 710 (a.k.a., substrate 121) can be configured to include a respective cavity in which the power converter assembly is disposed between a top surface 710-1 and the bottom surface 710-2 (a.k.a. surface 171) of the package substrate 710 (121). It is further noted that the power converter assembly associated with the package substrate 710 (substrate 121) is disposed between the side portion 710-3 and side portion 710-4 of the package substrate 710. Accordingly, the cavity in which the one or more instances of the power converter assembly reside is disposed between the top surface 710-1, bottom surface 710-2 (171), side portion 710-3, and side portion 710-4 of the package substrate 710.

As further shown, note that the output capacitors such as represented at least in part by the one or more capacitors COUTX can be disposed in a redistribution layer 135 disposed between the load 118 and the top surface 710-1 of the package substrate 710.

Yet further, as shown, the package substrate 710 (substrate 1 and 21) can be configured to include electrically conductive paths 721 extending between the power converter assembly and the redistribution layer 135. A first portion of the electrically conductive paths 721 can be configured to supply the output voltages generated from the power converter assembly. A second portion of the electrically conductive paths can be configured to support a return path for current to the ground (GND) node of the power converter assembly.

It is further noted that the package substrate 710 (substrate 121) can be configured to include one or more electrically conductive paths 722 extending between the power converter assembly and the connection interface 780. A first portion of the electrically conductive paths 722 can be configured to receive the input voltage Vin from one or more surface mount pads 132, 133, etc., and supply the one or more input voltages to the power converter assembly 120-X that converts the received input voltage into the output voltage 123 supplied to the load 118. A second portion of the electrically conductive paths can be configured to provide a return path for current to the ground (GND) node of the power converter assembly.

Additionally, as shown, the package substrate 710 can be configured to include one or more electrically conductive paths 723, where the electrically conductive paths that extend through the cavity of the packet substrate 710 and, as shown, directly connect nodes of the connection interface 780 to nodes on the redistribution layer 135.

Accordingly, the higher profile surface mount pads such as surface mount pad 132, surface mount pad 133, etc., provide a lower resistive path between the substrate 122 and the substrate 121 and corresponding power converter 120-X therein.

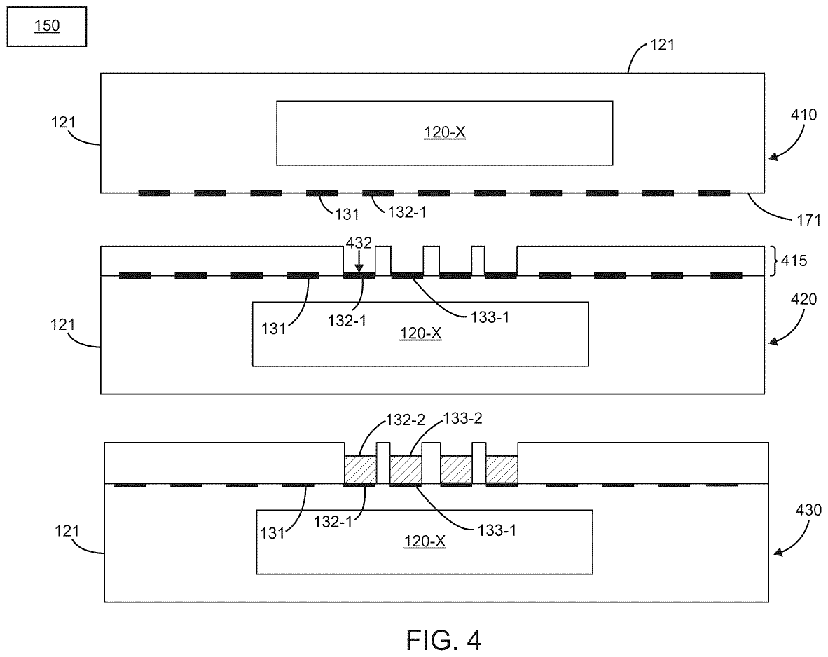

FIG. 4 is an example diagram illustrating fabrication of multiple high current surface pads on a substrate (i.e., circuit component) as discussed herein.

In processing operation 410, the fabricator 150 receives the substrate 121. The substrate 121 includes surface pad 131 and surface pad 132-1.

In processing operation 121, the fabricator 150 applies a respective layer of mask material 415 covering the surface pad 131. The respective layer of mask material 415 includes a respective opening 432 providing access to the base surface pad 132-1.

In processing operation 430, the fabricator 150 applies one or more layers of electrically conductive material through the opening 432 to a top surface of the surface pad 132-1 to produce the surface pad 132- to on the surface mount pad 132-1.

As shown, the fabricator 150 can be configured to produce any number of high profile surface mount pads on the substrate 121.

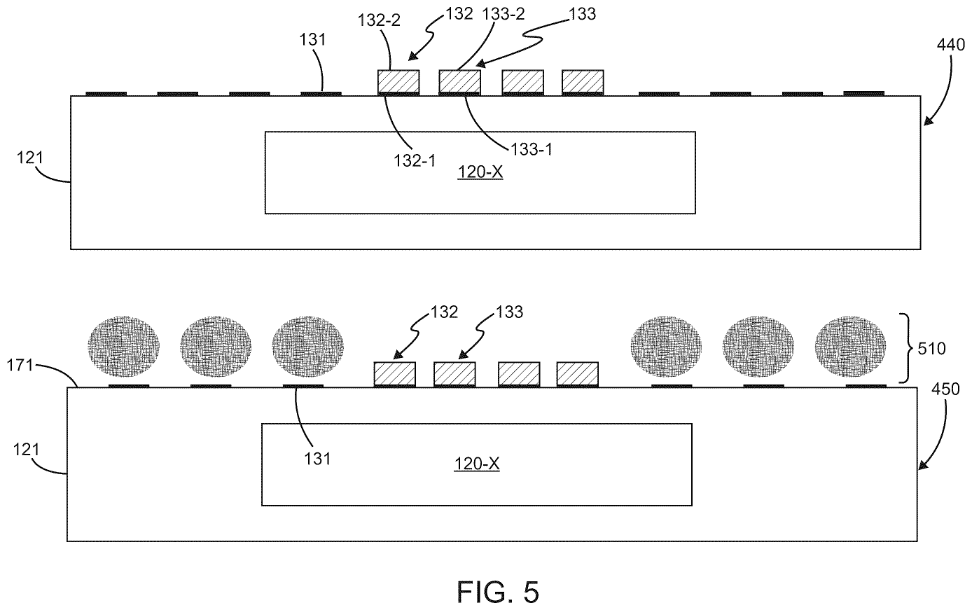

FIG. 5 is an example diagram illustrating implementation of multiple high current surface pads on a substrate as discussed herein.

In processing operation 440, the fabricator 150 removes the layer of mask material 415 to expose the top surface of the surface pad 131 as well as surface pad 132.

In processing operation 450, the fabricator 150 applies layer of the solder material 510 to one or more of the exposed surface pads on the surface 171.

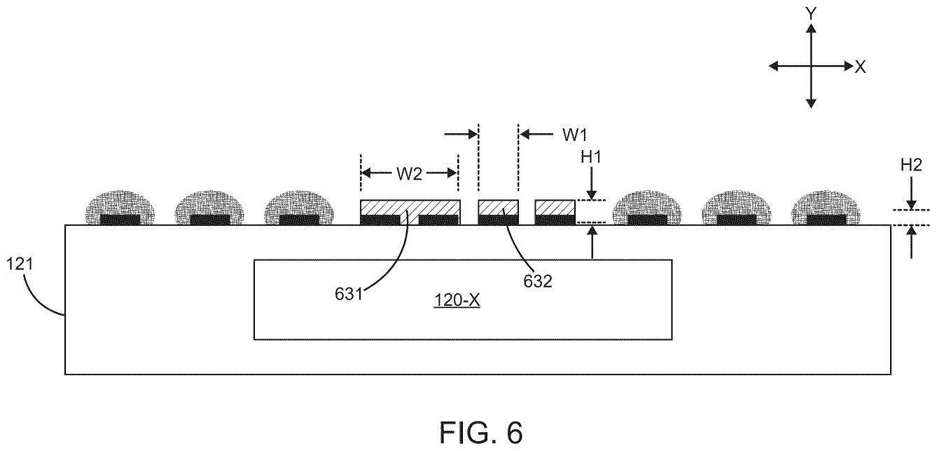

FIG. 6 is an example diagram illustrating different shapes of surface pads as discussed herein.

As previously discussed, the surface pads disposed on the substrate 121 can be any suitable size or shape.

In one example, the shape of the surface pads may be a mix of bar and random shapes (such as wider sized surface pads where W2>W1, and/or where taller sized surface pads H1>H2) to accommodate high current conveyance between the substrate 121 and another component. More specifically, the surface pad 631 disposed on the surface 171 of the substrate 121 has a width of W2; the surface pad 632 disposed on the surface 171 of the substrate 121 has a width of W1. In this example, the width W2 is greater than the width W1.

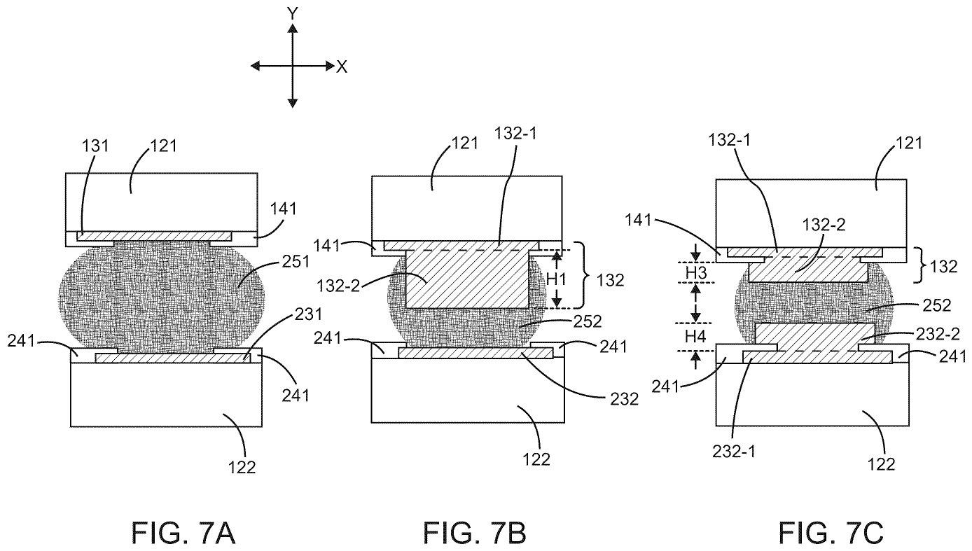

FIG. 7A is an example diagram illustrating implementation of a circuit path between a first standard surface pad and a second standard surface pad as discussed herein.

As previously discussed, the electrical connectivity between the surface mount pad 131 (such as of height H2) disposed on the substrate 121 and the surface mount pad 231 (such as of height H1 or other suitable height) can be achieved via the mass of solder 251 disposed between the bottom surface of the surface pad 131 and the top surface of the surface pad 231. The mass of solder 251 is approximately elliptical. In such an instance, the solder fills the gap between the bottom surface of the surface pad 131 and the top surface of the surface pad 231. It is noted that the amount of solder 251 is greater than the amount of solder 252 in FIG. 7B in FIG. 7C because the surface pads 131 and 231 are low-profile.

FIG. 7B is an example diagram illustrating implementation of a circuit path between a standard surface pad and a high current surface pad as discussed herein.

As shown, the surface pad 132 (such as combination of surface pad 132-1 and surface pad 132-2) disposed on the substrate 121 can be configured in accordance with any suitable shape.

For example, the surface pad 132 disposed on the substrate 121 can be fabricated to have a height of H1 (high-profile surface mount pad) in a manner as previously discussed. The surface pad 232 disposed on the substrate 122 can be fabricated to a height of H2 (low-profile surface mount pad). As further shown, the mass of solder 252 fills in the gap between the bottom surface of the surface pad 132 and the top surface pad of the surface pad 232. The mass of solder 252 takes on a different shape than the mass of solder 251. Advantageously, the mass of solder 252 contacts the bottom surface of the surface pad 132 as well as sides of the surface pad 132.

Additionally, the surface mount pad 132-2 occupies a volume that would otherwise be solder 252.

FIG. 7C is an example diagram illustrating implementation of a circuit path between a first surface pad and a second surface pad as discussed herein.

As shown in this example, the surface pad 132 (such as combination of surface pad 132-1 and surface pad 132-2) disposed on the substrate 121 can be configured in accordance with any suitable shape and height.

For example, the surface pad 132 disposed on the substrate 121 can be fabricated (via fabricator 150) to have a height of H3 (such as medium-profile height with respect to the surface 171 of the substrate). The surface pad 232 disposed on the substrate 122 can be fabricated to a height of H4 (such as medium-profile height with respect to the surface 171 of the substrate). As further shown, the mass of solder 252 fills in the gap between the bottom surface of the surface pad 132 and the top surface pad of the surface pad 232. The mass of solder 252 in FIG. 7C takes on a different shape than the mass of solder 251 in FIG. 7A because of the supplemental conductive material used to fabricate the surface pad 132-2 and the supplemental conductive material used to fabricate the surface pad 232-2 on the base surface pad 232-1 resulting in enhanced height (H4) surface pad 232.

Advantageously, the mass of solder 252 contacts the bottom surface of the surface pad 132 as well as sides of the surface pad 132; the mass of solder 252 contacts the top surface of the surface pad 232 as well as sides of the surface pad 232. Additionally, the surface mount pad 132-2 occupies a volume that would otherwise be solder 252; the surface mount pad 232-2 occupies a volume that would otherwise be solder 252.

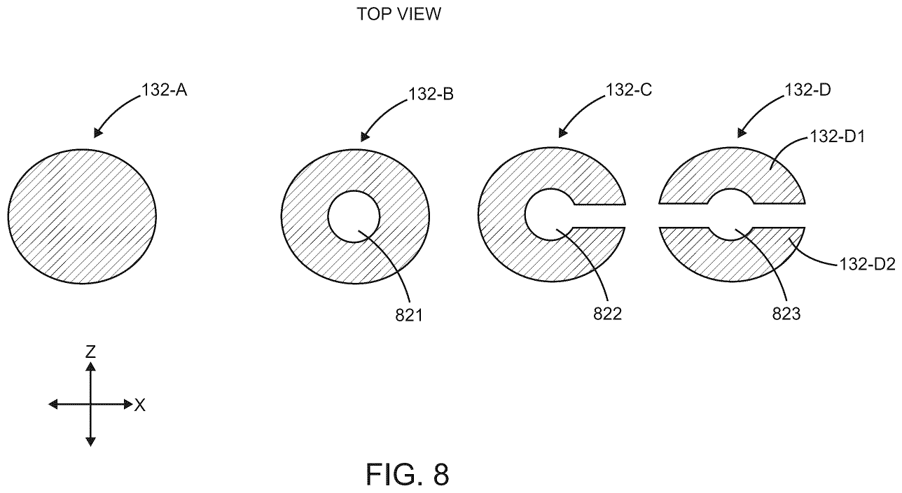

FIG. 8 is an example top view diagram illustrating different configurations of surface mount pads as discussed herein.

In this example, the surface pad 132-A (first example instance of the surface pad 132) does not include a void.

The surface pad 132-B (second example instance of the surface pad 132) includes the void 821 (a.k.a., cavity).

The surface pad 132-C (third example instance of the surface pad 132) includes the void 822 in the middle of the surface pad 132-C and extending to the side of the surface pad 132-C.

The surface pad 132-D (fourth example instance of the surface pad 132) includes the void 823 disposed in the middle of the surface pad 132-D and extending from the left side of the surface pad 132-D to the right side of the surface pad 132-D. This latter instance of the surface pad 132-D provides a separation between the first portion 132-D1 of the surface pad 132-D and a second portion 132-D2 of the surface pad 132-D.

Thus, it is further noted that each of the surface mount pads as discussed herein (such as one or more of surface pads 132, 133, 232, 233, etc.) disposed on the circuit substrate 121 or substrate 122 can be configured to include at least one void (such as any of the voids 821, 822, or 823), where the at least one void may further include a cavity disposed in a middle or side of the respective surface mount pad.

Still further, the surface mount pad (132, 133, 232, 232, etc.) can be configured to include a first void 823 (cavity) extending between a first side 132-D1 of the surface mount pad 132 and a second side 132-D2 of the surface mount pad 132.

Each of the voids 821, 822, 823, etc., can be configured to provide complete or partial separation between a first portion of the first surface mount pad and a second portion of the first surface mount pad. The separation and corresponding one or more void or cavities in the surface mount pad increases a respective surface area in which the mass of solder 252 adheres to the respective surface pad 132 or surface pad 232.

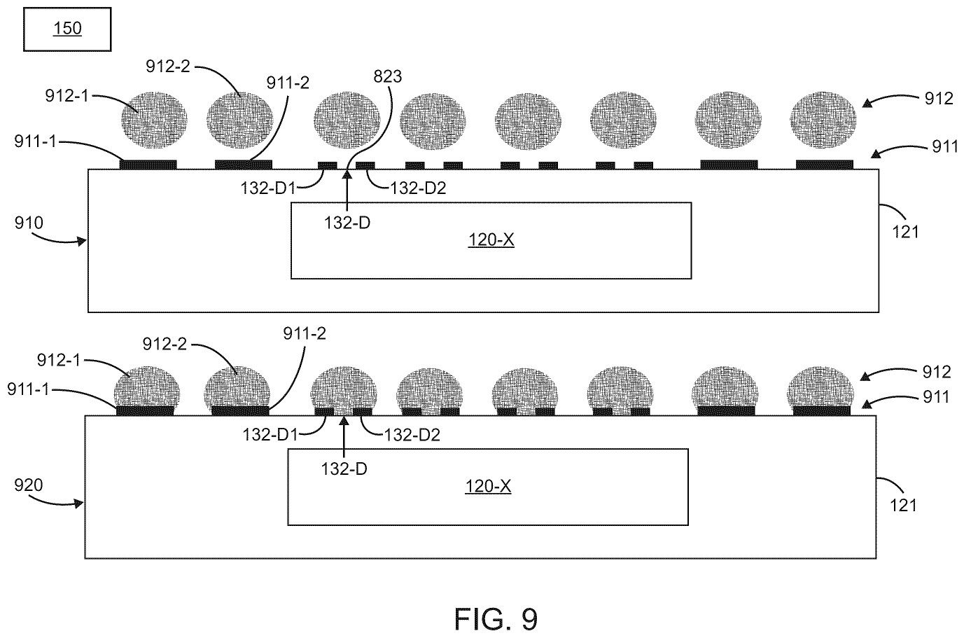

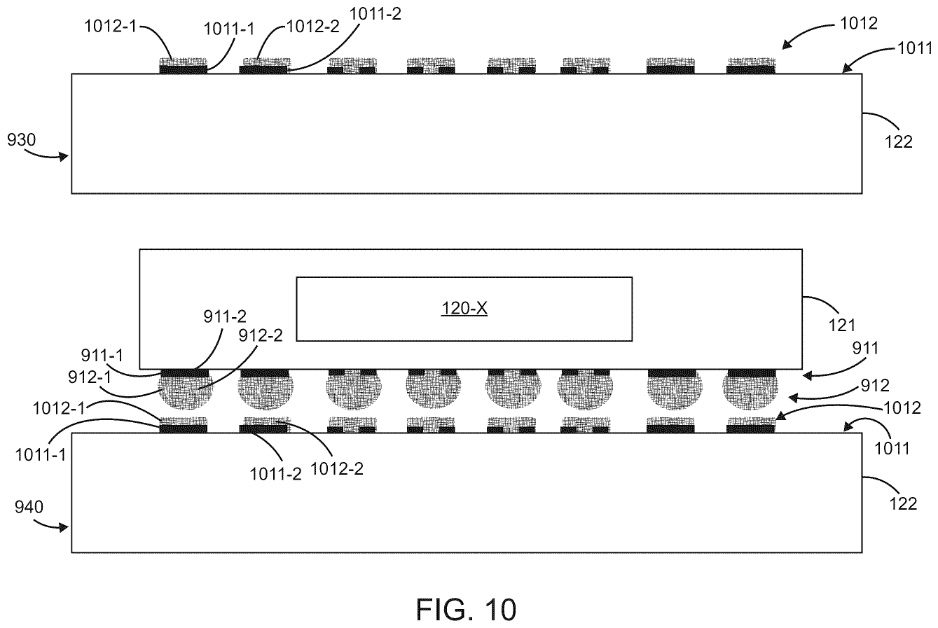

FIG. 9 and FIG. 10 are example diagrams illustrating a process of providing circuit path connectivity between multiple circuit assemblies as discussed herein.

In this example, in processing operations 910 and 920 as shown in FIG. 9, the fabricator 150 applies a respective mass of solder to each of the surface mount pads 911 (911-1, 911-2, etc.) disposed on the substrate 121. Each of the surface mount pads 911 can be fabricated in a similar manner as surface pad 131, 132, 133, etc.

As shown, the fabricator 150 applies a mass of solder 912-1 (such as solder paste) to the surface pad 911-1 disposed on a surface of the substrate 121. The fabricator 150 further applies a respective mass of solder 912-2 (such as solder paste) to the surface pad 911-2 disposed on the surface of the substrate 121, and so on. As previously discussed, each of the one or more of the surface pads can be configured to include a respective one or more voids or no void if desired.

As further shown in processing operation 930 in FIG. 10, the fabricator 150 applies the mass of solder 1012-1 to the surface mount pad 1011-1. The fabricator 150 applies the mass of solder 1012-2 to the surface mount pad 1011-2. In a similar manner, the fabricator 150 applies a respective mass of solder 1012 to each of the surface pads 1011 disposed on the substrate 122. Each of the surface pads 1011 can be fabricated in a similar manner as surface pads 231, 232, 233, 234, etc.

In processing operation 940, the fabricator 150 provides connectivity between respective surface pads on each of the substrate 121 and substrate 122.

For example, the fabricator 150 moves the substrate 121 closer to the substrate 122 such that the mass of solder 912-1 disposed on the first surface pad 911-1 physically contacts the mass of solder 1012-1 disposed on the surface pad 1011-1; the fabricator 150 moves the substrate 121 closer to the substrate 122 such that the mass of solder 912-2 disposed on the surface pad 911-2 physically contacts the mass of solder 1012-2 disposed on the surface pad 1011-2; and so on.

Additionally, subsequent to contact, the fabricator 150 applies appropriate heat to the respective masses of solder above a respective melting point associated with the solder paste. This liquefies the solder paste. Subsequent cooling of the liquid solder results in a corresponding remaining solid solder path extending between each of the surface pads 911 disposed on the substrate 121 and each of the surface pads 1011 disposed on the substrate 122.

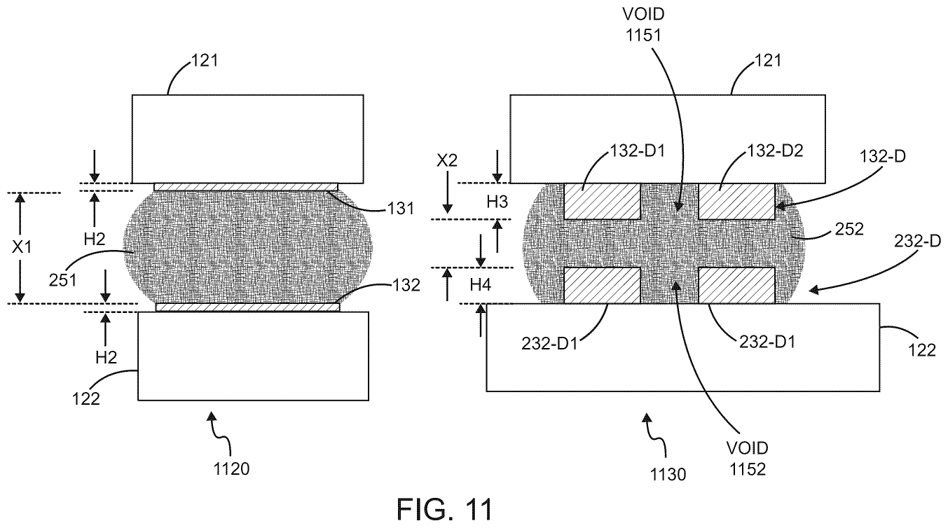

FIG. 11 is an example side view diagram illustrating different implementations of surface pads and corresponding solder joints to provide electrical connectivity as discussed herein.

As previously discussed, as shown by the configuration 1120, the electrical connectivity between the surface mount pad 131 (such as of height H2) disposed on the substrate 121 and the surface mount pad 132 (such as also of height H2) can be achieved via the mass of solder 251 disposed between the bottom surface of the surface pad 131 and the top surface of the surface pad 132. The mass of solder 251 is approximately elliptical. In such an instance, the solder fills the full gap X1 between the bottom surface of the surface pad 131 and the top surface of the surface pad 132.

In comparison, the surface pad 132-D disposed on the substrate 121 can be configured in accordance with any suitable shape such as in a manner as previously discussed in FIG. 8B or other configuration. For example, the surface pad 132-D disposed on the substrate 121 can be fabricated to have a height of H3. The surface pad 232-D disposed on the substrate 122 can be fabricated to a height of H4. The height H4 may be equal to or different than the height H3.

If desired, the surface pad 132-D can be configured to include the void 1151. The surface pad 232-D can be configured to include the void 1152.

As further shown, the mass of solder 252 fills in the gap X2 between the bottom surface of the surface pad 132-D and the top surface pad of the surface pad 232-D. As previously discussed, presence of the void 1151 in the surface pad 132-D and the presence of the void 1152 in the surface pad 232-D provides a greater surface area in which to support adherence of the mass of solder 252 to each of the surface pads 132-D and 232-D.

As previously discussed, the surface pad 132 can be implemented without a void. The surface pad 232 can be implemented without a void.

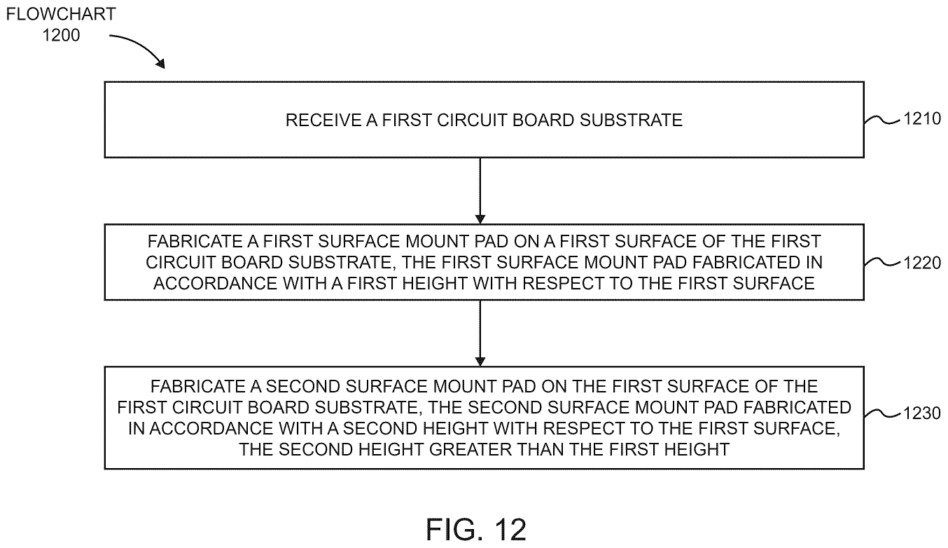

FIG. 12 is an example diagram illustrating a fabrication method of implementing one or more surface mount pads in a circuit assembly as discussed herein.

In processing operation 1210 of flowchart 1200, the fabricator 150 receives a first circuit substrate 121.

In processing operation 1220, the fabricator 150 fabricates a first surface mount pad (132) on a first surface of the first circuit substrate (121), where the first surface mount pad is fabricated in accordance with a first height H1.

In processing operation 1230, the fabricator 150 fabricates a second surface mount pad (131) on the first surface of the first circuit substrate, where the second surface mount pad (131) is fabricated in accordance with a second height H2. The height H1 is greater than the height H2.

Such an implementation supports conveyance of higher currents through the surface mount pad 132.

Note again that techniques herein are well suited for use in circuit assemblies requiring higher current throughput through a respective one or more surface mount pads. However, it should be noted that techniques herein are not limited to use in such applications and that the techniques discussed herein are well suited for other applications as well.

While this invention has been particularly shown and described with references to preferred examples thereof, it will be understood by those skilled in the art that various changes in form and details may be made therein without departing from the spirit and scope of the present application as defined by the appended claims. Such variations are intended to be covered by the scope of this present application. As such, the foregoing description of examples of the present application is not intended to be limiting. Rather, any limitations to the invention are presented in the following claims.

1. An apparatus comprising:
a first circuit substrate;
a first surface mount pad disposed on a first surface of the first circuit substrate, the first surface mount pad fabricated in accordance with a first height; and
a second surface mount pad disposed on the first surface of the first circuit substrate, the second surface mount pad fabricated in accordance with a second height, the first height being greater than the second height.

2. The apparatus as in claim 1, wherein the first surface mount pad includes at least one void, the at least one void including a first cavity disposed in a middle of the first surface mount pad.

3. The apparatus as in claim 1, wherein the first surface mount pad includes a first void extending between a first side of the first surface mount pad and a second side of the first surface mount pad, the first void operative to provide separation between a first portion of the first surface mount pad and a second portion of the first surface mount pad.

4. The apparatus as in claim 1 further comprising:
a layer of insulative material disposed on the first circuit substrate, the layer of material at least partially covering a first portion of a top surface of the second surface mount pad.

5. The apparatus as in claim 4 further comprising:
a first opening in the layer of insulative material, the first surface mount pad extending through the first opening of the insulative material; and
a second opening in the layer of insulative material, the second opening exposing a second portion of the top surface of the second surface mount pad.

6. The apparatus as in claim 1 further comprising:
a layer of insulative material disposed on the first surface of the first circuit substrate;
wherein a height of the layer of the insulative material with respect to the first surface of the first circuit substrate is less than the first height; and
wherein the height of the layer of the insulative material with respect to the first surface of the first circuit substrate is greater than the second height.

7. The apparatus as in claim 1 further comprising:
a first mass of solder material in contact with the first surface mount pad;
a second mass of solder material in contact the second surface mount pad; and
wherein at least a portion of the first mass of solder material contacts a top surface of the first surface mount pad and a side surface of the first surface mount pad.

8. The apparatus as in claim 1 further comprising:
a second circuit substrate including a third surface mount pad and a fourth surface mount pad, the third surface mount pad and the fourth surface mount pad disposed on a first surface of the second circuit substrate;
a first solder joint extending between the first surface mount pad and the third surface mount pad; and
a second solder joint extending between the second surface mount pad and the fourth surface mount pad.

9. The apparatus as in claim 8, wherein the third surface mount pad is fabricated in accordance with a third height;
wherein the fourth surface mount pad is fabricated in accordance with a fourth height; and
wherein the third height is greater than the fourth height.

10. The apparatus as in claim 9, wherein a first gap filled with solder between the first surface mount pad and the third surface mount pad is less than a second gap filled with solder between the second surface mount pad and the fourth surface mount pad.

11. The apparatus as in claim 1 further comprising:
a second circuit substrate including a third surface mount pad and a fourth surface mount pad, the third surface mount pad and the fourth surface mount pad disposed on a first surface of the second circuit substrate;
a first solder joint extending between the first surface mount pad and the third surface mount pad; and
a second solder joint extending between the second surface mount pad and the surface mount pad.

12. The apparatus as in claim 11, wherein the first surface of the first circuit substrate is spaced apart from the first surface of the second circuit substrate by a distance X; and
wherein a magnitude of the first height of the first surface mount pad is between 50 percent and 90 percent of the distance X.

13. The apparatus as in claim 1, wherein the first circuit substrate includes an embedded voltage regulator circuit operative to: i) receive an input voltage from the first surface mount pad, ii) convert the input voltage into an output voltage, and iii) output the output voltage from a second surface of the first circuit substrate to a load, the second surface of the first circuit substrate facing an opposite direction than the second surface of the first circuit substrate.

14. The apparatus as in claim 1, wherein the first surface mount pad includes a base surface mount pad and a supplemental conductive element fabricated on the base surface mount pad, the base surface mount pad being disposed between the first circuit substrate and the supplemental conductive element; and
wherein a height of the base surface mount pad is substantially equal to the second height.

15. An apparatus comprising:
a first circuit substrate; and
a first surface mount pad disposed on a first surface of the first circuit substrate, the first surface mount pad including a base surface mount pad and a supplemental conductive element fabricated on the base surface mount pad such that the base surface mount pad is disposed between the first circuit substrate and the supplemental conductive element.

16. The apparatus as in claim 15 further comprising:
a second surface mount pad disposed on a second circuit substrate;
a mass of solder providing an electrically conductive path between the second surface mount pad and the supplemental conductive element; and
wherein presence of the supplemental conductive element is operative to replace solder otherwise needed to electrically connect the base surface mount pad to the second surface mount pad.

17. A method comprising:
receiving a first circuit substrate;
fabricating a first surface mount pad on a first surface of the first circuit substrate, the first surface mount pad fabricated in accordance with a first height with respect to the first surface; and
fabricating a second surface mount pad on the first surface of the first circuit substrate, the second surface mount pad fabricated in accordance with a second height with respect to the first surface, the second height greater than the first height.

18. The method as in claim 17, wherein an initial height of the second surface mount pad with respect to the first surface is substantially equal to the first height of the first surface mount pad; and
wherein fabricating the second surface mount pad further includes:
applying a mask layer to the first surface of the first circuit, the mask layer covering the first surface mount pad, the mask layer including an opening exposing the second surface mount pad; and
applying electrically conductive material though the opening to increase a height of the second surface mount pad with respect to the first surface, the mask layer preventing application of the electrically conductive material to the first surface mount pad.

19. The method as in claim 18, wherein fabricating the second surface mount pad further includes:
removing the mask layer from the first surface to expose the first surface mount pad and the second surface mount pad.

20. The method as in claim 17, wherein fabricating the second surface mount pad includes:
fabricating the second surface mount pad to include at least one void to increase an exposed surface area of the second surface mount pad.
